(19) United States
(12) Patent Application Publication
(10) Pub. No.: US 2020/0176418 A1
(43) Pub. Date: Jun. 4, 2020

(54) DUAL-DIE MEMORY PACKAGE

(71) Applicant: Nanya Technology Corporation, New Taipei city (TW)

(72) Inventor: Hsin-Mao HUANG, Taoyuan City (TW)

(21) Appl. No.: 16/254,599

(22) Filed: Jan. 23, 2019

Related U.S. Application Data
(60) Provisional application No. 62/775,369, filed on Dec. 4, 2018.

(51) Int. Cl. H01L 25/065

(52) U.S. Cl. CPC H01L 25/0657; H01L 2225/06586; H01L 2225/06513; H01L 2225/0651

(57) ABSTRACT

A dual-die memory package includes a package substrate, a first die, a second die, a bonding wire, and a conductive pillar. The first die is disposed on the package substrate and includes a first conductive pad and a first bonding pad. The first conductive pad and the first bonding pad are disposed on a surface of the first die facing away from the package substrate. The second die is disposed on a side of the first die away from the package substrate. The second die includes a second conductive pad disposed on a surface of the second die facing the first die. The first bonding pad is electrically coupled to the package substrate through the bonding wire. The first conductive pad is electrically coupled to the second conductive pad through the conductive pillar.

### RELATED APPLICATIONS

This application claims priority to U.S. Provisional Application Ser. No. 62/775,369, filed Dec. 4, 2018, which is herein incorporated by reference in its entirety.

### BACKGROUND

### Technical Field

The present disclosure relates to a dual-die memory package, and more particularly, to a dual-die memory package without through-silicon via (TSV).

### Description of Related Art

In recent years, 3D die stacking techniques have been widely adopted to produce high capacity memory packages in a small form factor. A 3D-stacked memory package typically includes multiple vertically stacked semiconductor dies that are interconnected by through-silicon vias (TSV) and microbumps. However, in such TSV-based memory devices, the adoption of TSV may introduce additional manufacturing complexity and increase the production cost accordingly.

### SUMMARY

In view of the foregoing, one of the objects of the present disclosure is to provide a 3D-stacked memory package without TSV.

To achieve the objective stated above, in accordance with some embodiments of the present disclosure, a dual-die memory package includes a package substrate, a first die, a second die, a bonding wire, and a conductive pillar. The first die is disposed on the package substrate and includes a first conductive pad and a first bonding pad. The first conductive pad and the first bonding pad are disposed on a surface of the first die facing away from the package substrate. The second die is disposed on a side of the first die away from the package substrate. The second die includes a second conductive pad disposed on a surface of the second die facing the first die. The first bonding pad is electrically coupled to the package substrate through the bonding wire. The first conductive pad is electrically coupled to the second conductive pad through the conductive pillar.

In one or more embodiments of the present disclosure, the first conductive pad and the second conductive pad are aligned in a direction perpendicular to the surface of the first die. The conductive pillar is located between and in contact with the first conductive pad and the second conductive pad.

In one or more embodiments of the present disclosure, a vertical projection of the second conductive pad on the surface of the first die entirely overlaps the first conductive pad.

In one or more embodiments of the present disclosure, the first conductive pad and the second conductive pad are misaligned in a direction perpendicular to the surface of the first die.

In one or more embodiments of the present disclosure, at least a part of a vertical projection of the second conductive pad on the surface of the first die does not overlap the first conductive pad.

In one or more embodiments of the present disclosure, the first die further includes a redistribution layer disposed on the surface of the first die and electrically connected to the first conductive pad. The conductive pillar is located between and in contact with the redistribution layer and the second conductive pad.

In one or more embodiments of the present disclosure, the second die further includes a redistribution layer disposed on the surface of the second die and electrically connected to the second conductive pad. The conductive pillar is located between and in contact with the redistribution layer and the first conductive pad.

In one or more embodiments of the present disclosure, the first die further includes a first redistribution layer disposed on the surface of the first die and electrically connected to the first conductive pad. The second die further includes a second redistribution layer disposed on the surface of the second die and electrically connected to the second conductive pad. The conductive pillar is located between and in contact with the first redistribution layer and the second redistribution layer.

In one or more embodiments of the present disclosure, an end of the first redistribution layer away from the first conductive pad is aligned with an end of the second redistribution layer away from the second conductive pad.

In one or more embodiments of the present disclosure, the conductive pillar is in contact with an end of the first redistribution layer away from the first conductive pad and an end of the second redistribution layer away from the second conductive pad.

In one or more embodiments of the present disclosure, two ends of the bonding wire are in contact with the first bonding pad and the package substrate respectively.

In one or more embodiments of the present disclosure, the first die further includes a redistribution layer disposed on the surface of the first die and electrically connected to the first bonding pad. Two ends of the bonding wire are in contact with the redistribution layer and the package substrate respectively.

In one or more embodiments of the present disclosure, an end of the redistribution layer away from the first bonding pad extends to an edge of the first die.

In one or more embodiments of the present disclosure, two ends of the bonding wire are in contact with the package substrate and an end of the redistribution layer away from the first bonding pad respectively.

In one or more embodiments of the present disclosure, the bonding wire partially extends in a gap formed between the first die and the second die.

In one or more embodiments of the present disclosure, a vertical projection of the first die on the package substrate is spaced apart from an end of the bonding wire in contact with the package substrate.

In one or more embodiments of the present disclosure, the first conductive pad corresponds to the second conductive pad, and the first die and the second die have identical structure.

In one or more embodiments of the present disclosure, the dual-die memory package further includes a die attach film disposed between the first die and the package substrate.

In one or more embodiments of the present disclosure, the dual-die memory package further includes a molding compound encapsulating the first die, the second die, the bonding wire, and the conductive pillar.

In one or more embodiments of the present disclosure, the dual-die memory package further includes a plurality of solder balls disposed on a side of the package substrate away from the first die.

In sum, the dual-die memory package of the present disclosure includes two dies (i.e., the first die and the second die) stacked on the substrate. The two dies are in a face-to-face configuration, with the conductive pads of the two dies facing each other and electrically coupled through the conductive pillar positioned therebetween. The first die, which is positioned at the bottom, further includes the bonding pad electrically coupled to the package substrate through the bonding wire to facilitate die-to-package communication. The structural configuration described above enables 3D die stacking without the need for TSV.

### BRIEF DESCRIPTION OF THE DRAWINGS

The present disclosure can be more fully understood by reading the following detailed description of the embodiment, with reference made to the accompanying drawings as follows:

FIG. 1 illustrates a schematic cross-sectional view of a dual-die memory package in accordance with some embodiments of the present disclosure;

FIG. 2 illustrates a schematic cross-sectional view of a dual-die memory package in accordance with some embodiments of the present disclosure;

FIG. 3 illustrates a schematic cross-sectional view of a dual-die memory package in accordance with some embodiments of the present disclosure;

FIG. 4 illustrates a schematic cross-sectional view of a dual-die memory package in accordance with some embodiments of the present disclosure; and

FIG. 5 illustrates a schematic cross-sectional view of a dual-die memory package in accordance with some embodiments of the present disclosure.

### DETAILED DESCRIPTION

Reference will now be made in detail to the present embodiments of the present disclosure, examples of which are illustrated in the accompanying drawings. Wherever possible, the same reference numerals are used in the drawings and the description to refer to the same or like parts.

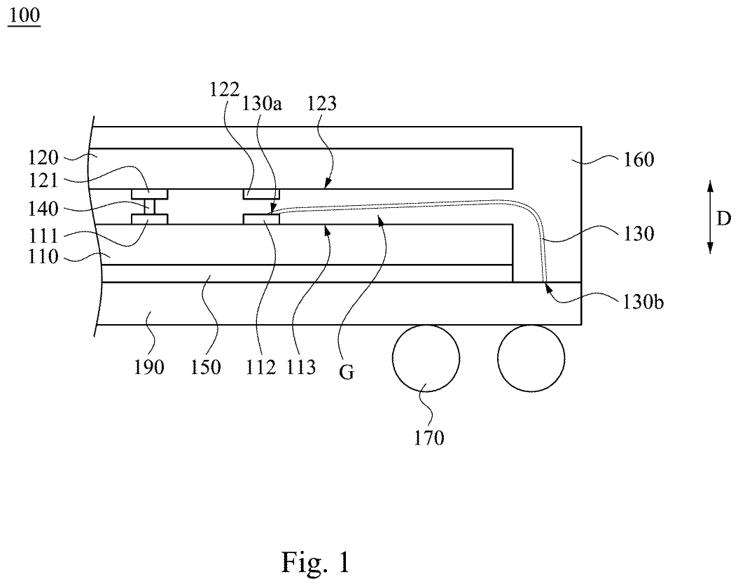

Reference is made to FIG. 1, which illustrates a schematic cross-sectional view of a dual-die memory package 100 in accordance with some embodiments of the present disclosure. The dual-die memory package 100 includes a package substrate 190, a first die 110, a second die 120, a bonding wire 130, and a conductive pillar 140. The first die 110 is disposed on the package substrate 190, and the second die 120 is disposed on a side of the first die 110 away from the package substrate 190. In other words, the first die 110 and the second die 120 are stacked over the package substrate 190, with the first die 110 being at the bottom and the second die 120 being on the top. In some embodiments, the dual-die memory package 100 is a 3DS 2H DDR4 SDRAM (3D-stack 2-height double data rate fourth-generation synchronous dynamic random-access memory) package.

As shown in FIG. 1, the second die 120 includes a second conductive pad 121 disposed on a bottom surface 123 of the second die 120 facing the first die 110 (i.e., the second die 120 “faces down”). The first die 110 includes a first conductive pad 111 and a first bonding pad 112. The first conductive pad 111 and the first bonding pad 112 are disposed on a top surface 113 of the first die 110 facing away from the package substrate 190 (i.e., the first die 110 “faces up”, such that the first die 110 and the second die 120 are in a face-to-face configuration). The first conductive pad 111 is electrically coupled to the second conductive pad 121 of the second die 120 through the conductive pillar 140 to facilitate inter-die communication. The first bonding pad 112 is electrically coupled to the package substrate 190 through the bonding wire 130 to facilitate die-to-package communication.

In some embodiments, the conductive pillar 140 is a copper pillar, and a width and a height of the copper pillar is between about 30 μm to about 70 μm. In some embodiments, the bonding wire 130 includes Au, Ag, Cu, other suitable conductive materials, or combinations thereof.

In some embodiments, as shown in FIG. 1, the dual-die memory package 100 further includes a die attach film 150 disposed between the first die 110 and the package substrate 190. The die attach film 150 is an adhesive that serves to attach the first die 110 to an upper surface of the package substrate 190.

In some embodiments, as shown in FIG. 1, the dual-die memory package 100 further includes a molding compound 160 encapsulating the first die 110, the second die 120, the bonding wire 130, and the conductive pillar 140. Specifically, the molding compound 160 covers top sides of the package substrate 190 and the second die 120 and fills in a gap G formed between the first die 110 and the second die 120. The molding compound 160 serves to protect elements embedded therein.

In some embodiments, as shown in FIG. 1, the dual-die memory package 100 further includes a plurality of solder balls 170 disposed on a side of the package substrate 190 away from the first die 110. The solder balls 170 serve as an external connection interface and are configured to be electrically coupled to a circuit board or other electronic components (not shown).

In some embodiments, as shown in FIG. 1, the first die 110 and the second die 120 have identical structure. The first conductive pad 111 of the first die 110 corresponds to the second conductive pad 121 of the second die 120. The second die 120 further includes a second bonding pad 122 which corresponds to the first bonding pad 112 of the first die 110. With the first die 110 and the second die 120 being structurally identical, the manufacturing complexity of the dual-die memory package 100 may be reduced.

In some embodiments, the first die 110 acts as a master die and the second die 120 acts as a slave die. The first bonding pad 112 of the first die 110 is the only die-to-package communication interface. In other words, all the traffic to the stacked dies goes through the first bonding pad 112, and the second bonding pad 122 has no function. The present disclosure is not limited to such master-slave configuration. In some other embodiments, the second conductive pad 122 may be electrically coupled to the package substrate 190 through another bonding wire (not shown).

In some embodiments, as shown in FIG. 1, the first conductive pad 111 is aligned with the second conductive pad 121 in a direction D perpendicular to the top surface 113 of the first die 110. Specifically, a vertical projection (i.e., a projection along the direction D) of the second conductive pad 121 on the top surface 123 of the first die 110 entirely overlaps the first conductive pad 111. In such embodiments, the conductive pillar 140 is located between the first conductive pad 111 and the second conductive pad 121, and two ends of the conductive pillar 140 are in contact with the first conductive pad 111 and the second conductive pad 121 respectively.

In some embodiments, as shown in FIG. 1, the bonding wire 130 partially extends in the gap G between the first die 110 and the second die 120. The bonding wire 130 has two opposite ends, including a first end 130a and a second end 130b in contact with the first bonding pad 112 and the package substrate 190 respectively. A vertical projection of the first die 110 on the package substrate 190 is spaced apart from the second end 130b. In other words, the second end 130b of the bonding wire 130 is connected to a portion of package substrate 190 not being overlaid by the first die 110 in the direction D.

Although the first die 110 is described above with a single conductive pad (i.e., the first conductive pad 111) and a single bonding pad (i.e., the first bonding pad 112), it is only for the convenience of description. The first die 110 may include a plurality of the first conductive pads 111 and a plurality of the first bonding pads 112 disposed on the top surface 113. For example, the first conductive pads 111 and the first bonding pads 112 may be arranged along a direction perpendicular to the cross-sectional plane shown in FIG. 1. Similarly, the second die 120 may include a plurality of the second conductive pads 121 positioned corresponding to the first conductive pads 111. The dual-die memory device 100 may include a plurality of the conductive pillars 140, each electrically coupling a corresponding one of the first conductive pads 111 to a corresponding one of the second conductive pads 121. The dual-die memory device 100 may include a plurality of the bonding wires 130, each electrically coupling a corresponding one of the first bonding pads 112 to the package substrate 190.

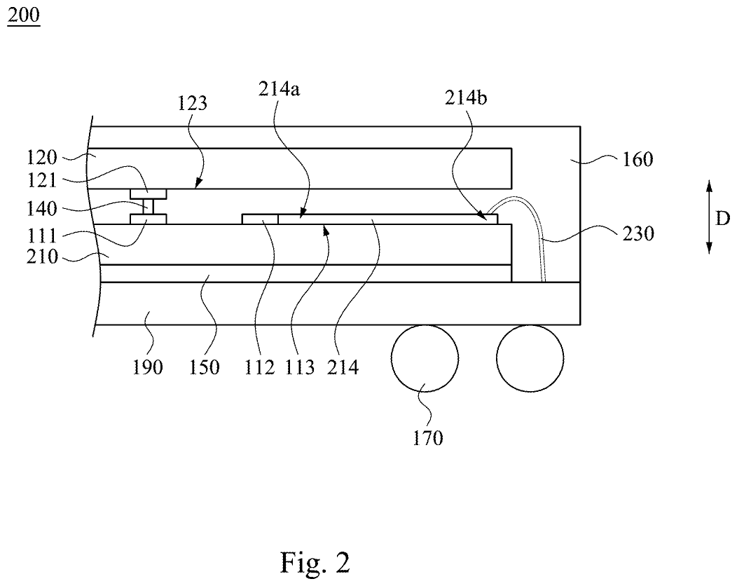

Reference is made to FIG. 2, which illustrates a schematic cross-sectional view of a dual-die memory package 200 in accordance with some embodiments of the present disclosure. The dual-die memory package 200 includes a package substrate 190, a first die 210, a second die 120, a bonding wire 230, and a conductive pillar 140. Like reference numerals refer to like elements that are substantially identical to those previously described with reference to FIG. 1. Descriptions regarding these elements are not repeated herein for brevity.

As shown in FIG. 2, in some embodiments, the bonding wire 230 is not in direct contact with the first bonding pad 112. The first die 210 of the dual-die memory package 200 further includes a redistribution layer (RDL) 214 through which the bonding wire 230 is electrically coupled to the first bonding pad 112. The redistribution layer 214 is disposed on the top surface 113 of the first die 210. The redistribution layer 214 has two opposite ends, including a first end 214a electrically connected to the first bonding pad 112, and a second end 214b extending to an edge of the first die 210. Two ends of the bonding wire 230 are in contact with the second end 214b of the redistribution layer 214 and the package substrate 190 respectively. With the redistribution layer 214, the bonding wire 230 may be formed with a shorter length (compared to the bonding wire 130 of the dual-die memory package 100) during the wire bonding process.

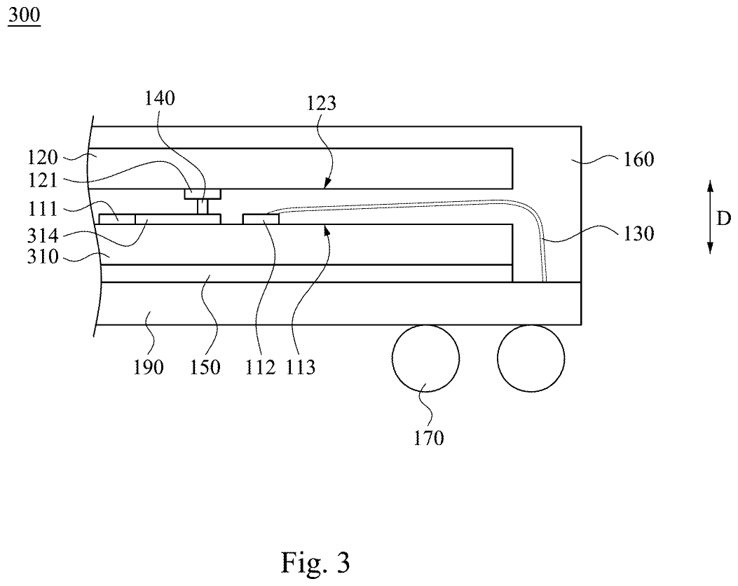

Reference is made to FIG. 3, which illustrates a schematic cross-sectional view of a dual-die memory package 300 in accordance with some embodiments of the present disclosure. The dual-die memory package 300 includes a package substrate 190, a first die 310, a second die 120, a bonding wire 130, and a conductive pillar 140. Like reference numerals refer to like elements that are substantially identical to those previously described with reference to FIG. 1. Descriptions regarding these elements are not repeated herein for brevity.

As shown in FIG. 3, in some embodiments, the first conductive pad 111 of the first die 310 is misaligned with the second conductive pad 121 of the second die 120 in the direction D. Specifically, the misalignment between the first conductive pad 111 and the second conductive pad 121 means at least a part of the vertical projection of the second conductive pad 121 on the top surface 113 of the first die 310 does not overlap the first conductive pad 111. In some embodiments as illustrated by FIG. 3, the first conductive pad 111 is shifted leftward relative to the second conductive pad 121.

As shown in FIG. 3, in order to cope with the misalignment between the first conductive pad 111 and the second conductive pad 121, the first die 310 further includes a redistribution layer 314 electrically connected to the first conductive pad 111. The redistribution layer 314 is disposed on the top surface 113 of the first die 310 and extends to the underneath of the second conductive pad 121. The conductive pillar 140 is located between the redistribution layer 314 and the second conductive pad 121, and two ends of the conductive pillar 140 are in contact with the redistribution layer 314 and the second conductive pad 121 respectively.

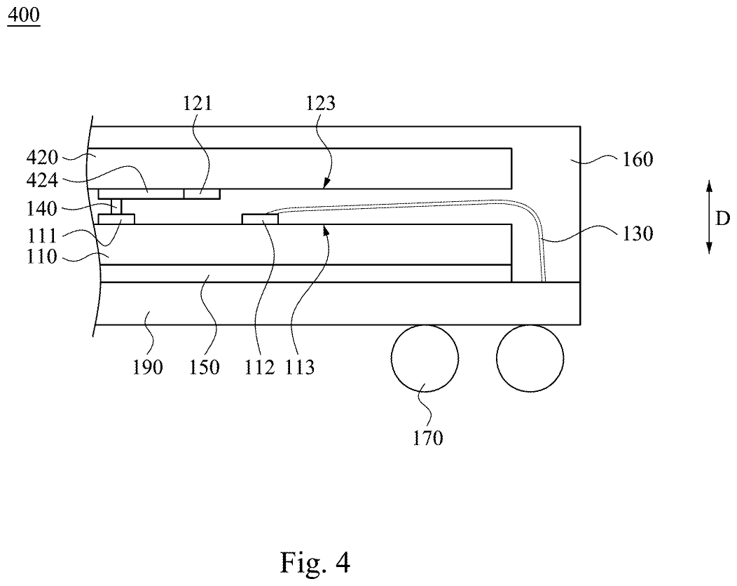

Reference is made to FIG. 4, which illustrates a schematic cross-sectional view of a dual-die memory package 400 in accordance with some embodiments of the present disclosure. The dual-die memory package 400 includes a package substrate 190, a first die 110, a second die 420, a bonding wire 130, and a conductive pillar 140. Like reference numerals refer to like elements that are substantially identical to those previously described with reference to FIG. 1. Descriptions regarding these elements are not repeated herein for brevity.

As shown in FIG. 4, the first conductive pad 111 and the second conductive pad 121 are misaligned in a manner similar to that of the embodiments illustrated by FIG. 3. The second die 420 further includes a redistribution layer 424 electrically connected to the second conductive pad 121. The redistribution layer 424 is disposed on the bottom surface 123 of the second die 420 and extends over the top of the first conductive pad 111. The conductive pillar 140 is located between the redistribution layer 424 and the first conductive pad 111, and two ends of the conductive pillar 140 are in contact with the redistribution layer 424 and the first conductive pad 111 respectively.

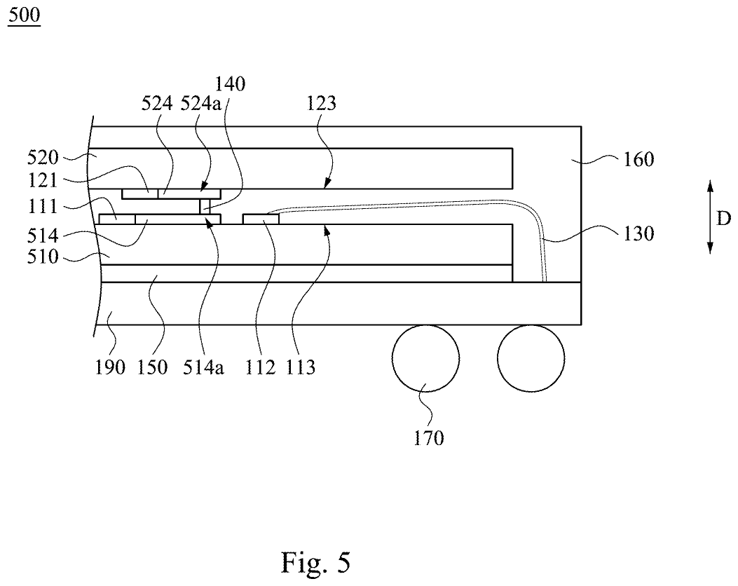

Reference is made to FIG. 5, which illustrates a schematic cross-sectional view of a dual-die memory package 500 in accordance with some embodiments of the present disclosure. The dual-die memory package 500 includes a package substrate 190, a first die 510, a second die 520, a bonding wire 130, and a conductive pillar 140. Like reference numerals refer to like elements that are substantially identical to those previously described with reference to FIG. 1. Descriptions regarding these elements are not repeated herein for brevity.

As shown in FIG. 5, in some embodiments, the first conductive pad 111 of the first die 510 is misaligned with the second conductive pad 121 of the second die 520 in the direction D. However, the vertical projection of the second conductive pad 121 on the top surface 113 of the first die 510 partially overlaps the first conductive pad 111. The first die 510 further includes a first redistribution layer 514 disposed on the top surface 113 of the first die 510 and electrically connected to the first conductive pad 111. The second die 520 further includes a second redistribution layer 524 disposed on the bottom surface 123 of the second die 520 and electrically connected to the second conductive pad 121. The first redistribution layer 514 and the second redistribution layer 524 both extend rightward, and an end 514a of the first redistribution layer 514 away from the first conductive pad 111 is vertically aligned with an end 524a of the second redistribution layer 524 away from the second conductive pad 121. The conductive pillar 140 is located between the first redistribution layer 514 and the second redistribution layer 524, and two ends of the conductive pillar 140 are in contact with the end 514a of the first redistribution layer 514 and the end 524a of the second redistribution layer 524 respectively.

In sum, the dual-die memory package of the present disclosure includes two dies (i.e., the first die and the second die) stacked on the substrate. The two dies are in a face-to-face configuration, with the conductive pads of the two dies facing each other and electrically coupled through the conductive pillar positioned therebetween. The first die, which is positioned at the bottom, further includes the bonding pad electrically coupled to the package substrate through the bonding wire to facilitate die-to-package communication. The structural configuration described above enables 3D die stacking without the need for TSV.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

1. A dual-die memory package, comprising:
a package substrate;
a first die disposed on the package substrate and comprising:
a first conductive pad disposed on a surface of the first die facing away from the package substrate; and
a first bonding pad disposed on the surface of the first die;
a second die disposed on a side of the first die away from the package substrate and comprising a second conductive pad, wherein the second conductive pad is disposed on a surface of the second die facing the first die;
a bonding wire through which the first bonding pad is electrically coupled to the package substrate; and
a conductive pillar through which the first conductive pad is electrically coupled to the second conductive pad.

2. The dual-die memory package of claim 1, wherein the first conductive pad and the second conductive pad are aligned in a direction perpendicular to the surface of the first die, and the conductive pillar is located between and in contact with the first conductive pad and the second conductive pad.

3. The dual-die memory package of claim 2, wherein a vertical projection of the second conductive pad on the surface of the first die entirely overlaps the first conductive pad.

4. The dual-die memory package of claim 1, wherein the first conductive pad and the second conductive pad are misaligned in a direction perpendicular to the surface of the first die.

5. The dual-die memory package of claim 4, wherein at least a part of a vertical projection of the second conductive pad on the surface of the first die does not overlap the first conductive pad.

6. The dual-die memory package of claim 4, wherein the first die further comprises a redistribution layer disposed on the surface of the first die and electrically connected to the first conductive pad, and the conductive pillar is located between and in contact with the redistribution layer and the second conductive pad.

7. The dual-die memory package of claim 4, wherein the second die further comprises a redistribution layer disposed on the surface of the second die and electrically connected to the second conductive pad, and the conductive pillar is located between and in contact with the redistribution layer and the first conductive pad.

8. The dual-die memory package of claim 4, wherein the first die further comprises a first redistribution layer disposed on the surface of the first die and electrically connected to the first conductive pad, the second die further comprises a second redistribution layer disposed on the surface of the second die and electrically connected to the second conductive pad, and the conductive pillar is located between and in contact with the first redistribution layer and the second redistribution layer.

9. The dual-die memory package of claim 8, wherein an end of the first redistribution layer away from the first conductive pad is aligned with an end of the second redistribution layer away from the second conductive pad.

10. The dual-die memory package of claim 8, wherein the conductive pillar is in contact with an end of the first redistribution layer away from the first conductive pad and an end of the second redistribution layer away from the second conductive pad.

11. The dual-die memory package of claim 1, wherein two ends of the bonding wire are in contact with the first bonding pad and the package substrate respectively.

12. The dual-die memory package of claim 1, wherein the first die further comprises a redistribution layer disposed on the surface of the first die and electrically connected to the first bonding pad, and two ends of the bonding wire are in contact with the redistribution layer and the package substrate respectively.

13. The dual-die memory package of claim 12, wherein an end of the redistribution layer away from the first bonding pad extends to an edge of the first die.

14. The dual-die memory package of claim 12, wherein two ends of the bonding wire are in contact with the package substrate and an end of the redistribution layer away from the first bonding pad respectively.

15. The dual-die memory package of claim 1, wherein the bonding wire partially extends in a gap formed between the first die and the second die.

16. The dual-die memory package of claim 1, wherein a vertical projection of the first die on the package substrate is spaced apart from an end of the bonding wire in contact with the package substrate.

17. The dual-die memory package of claim 1, wherein the first conductive pad corresponds to the second conductive pad, and the first die and the second die have identical structure.

18. The dual-die memory package of claim 1, further comprising a die attach film disposed between the first die and the package substrate.

19. The dual-die memory package of claim 1, further comprising a molding compound encapsulating the first die, the second die, the bonding wire, and the conductive pillar.

20. The dual-die memory package of claim 1, further comprising a plurality of solder balls disposed on a side of the package substrate away from the first die.
